(19) United States
(12) Patent Application Publication
(10) Pub. No.: US 2025/0252334 A1
(43) Pub. Date: Aug. 7, 2025

(54) TWO-DIMENSIONAL MATRIX QUANTUM DEVICE AND METHOD OF PRODUCING SAME

(71) Applicant: COMMISSARIAT A L'ENERGIE ATOMIQUE ET AUX ENERGIES ALTERNATIVES, Paris (FR)

(72) Inventor: Benoit BERTRAND, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/951,968

(22) Filed: Nov. 19, 2024

(30) Foreign Application Priority Data
Nov. 21, 2023 (FR) 2312825

(51) Int. Cl. G06N 10/40; G06N 10/20

(52) U.S. Cl. CPC G06N 10/40; G06N 10/20

(57) ABSTRACT

A quantum device has a plurality of quantum dots arranged in a two-dimensional matrix, a first gate level surmounting the plurality of quantum dots, a second gate level surmounting the first gate level, and a plurality of charge detectors capacitively coupled to the quantum dots. The plurality of charge detectors is integrated in one from among the first and second gate levels, each charge detector comprising a portion located between the gates of the gate level considered. The invention also relates to a method for producing such a quantum device.

### TECHNICAL FIELD

The present invention relates to the field of microelectronics and quantum electronics, in particular. It has a particularly advantageous application in manufacturing two-dimensional matrices of quantum bit or qubit devices integrating a compact charge detection system.

### PRIOR ART

The technical field is that of quantum information. The information bits called qubits are, in this case, produced in quantum dots which ensure the confinement of elementary charges (electrons or holes). Quantum information is, for example, coded on the spin of these particles.

To code and handle the information contained in quantum dots, for example, to initialise a quantum dot with a single charge, it is generally necessary to know the number of charges presented in the quantum dot(s). A solution to know this number of charges consists of disposing a charge detector in the proximity of the quantum dots.

The operation of such a charge detector is based on a capacitive coupling with the quantum dot. It is therefore advantageous to minimise the distance between the detector and the quantum dot to increase the sensitivity of the detector. The environment of the quantum dot also comprises the control elements of the qubits, typically control gates. The size and the sensitivity of the detector are therefore important aspects of a quantum bit device.

The charge detectors based on a conductive element connected to one or more charge reservoirs, such as single electron transistors (SET) or single-lead quantum dots (SLQD), are from among the most effective and the most sensitive detectors. They enable, in particular, an absolute reading of the number of charges in a quantum dot.

This type of charge detector however requires one or more bias gates to operate, as well as one or more carrier reservoirs. This considerably increases the size of this type of detector.

For one-dimensional (1D) quantum dot arrays, SET-type charge detectors can be integrated in the same plane as the quantum dots, facing these.

For two-dimensional (2D) quantum dot arrays, the size of the SET-type detectors limits the integration options of these detectors in the proximity of the quantum dots.

According to an option disclosed, for example, in the document, “Shared control of a 16 semiconductor quantum dot crossbar array, F. Borsoi et al., Condensed Matter, 2022”, the detectors are integrated at the periphery of the quantum dots. This limits the size of the 2D matrices to a few quantum dots per side.

According to another option disclosed in document FR3066297, SET-type detectors are integrated in a first plane located under a second plane comprising the quantum dots. These first and second planes are separated by at least one level comprising the bias gates of the detectors, and interconnections between the detectors and the quantum dots. The second plane comprising the quantum dots is also surmounted by control gate levels of the quantum dots. Such an architecture is very complex to achieve.

Moreover, the manufacturing stresses limit the proximity of the detectors to around 100 nm or more of the quantum dots to be detected.

The control and/or bias gates can also partially shield the quantum dots for the detectors, which reduces the intensity of the capacitive coupling and the sensitivity of the detector.

Therefore, there is a need relating to a quantum dot two-dimensional (2D) matrix quantum device comprising smaller and/or better integrated charge detectors. An aim of the invention is to meet this need, and to overcome at least partially the disadvantages of the known solutions.

In particular, an aim of the invention is a quantum device comprising charge detectors having an improved compactness. Another aim of the invention is a method for producing such a device.

Other aims, features and advantages of the present invention will appear upon examining the description below and the accompanying drawings. It is understood that other advantages can be incorporated.

### SUMMARY

To achieve this aim, according to an embodiment, a quantum device is provided, comprising:
a semiconductive layer in which is formed, during the operation of the quantum device, a plurality of quantum dots arranged in a two-dimensional matrix,
a plurality of charge detectors capacitively coupled to the quantum dots of the plurality of quantum dots,
a first set of gates comprising control gates of the quantum dots, surmounting the semiconductive layer, and
a second set of gates comprising gates intended to form at least one charge reservoir for the charge detectors.

Advantageously, each charge detector comprises a portion located between the gates of the first set of gates. Preferably, the gates of the second set of gates form one single charge reservoir common to each charge detector.

Thus, contrary to the solution disclosed by document FR3066297 in which the charge detectors are disposed on a distinct level and separated from the control gate levels of the quantum dots, the device according to the invention integrates the detectors directly within the control gate levels of the quantum dots. This makes it possible to improve the compactness of the device. The detectors can further be closer to the quantum dots. The device architecture proposed by the present invention is also less complex to achieve by standard technological microelectronics methods.

Another aspect of the invention relates to a method for producing such a quantum device, comprising:
a formation of a semiconductive layer intended to comprise a plurality of quantum dots arranged in a two-dimensional matrix,
a formation of a first set of gates comprising control gates of the quantum dots, surmounting the semiconductive layer,
a formation of a second set of gates comprising gates intended to form at least one charge reservoir for the charge detectors (4, 4a, 4′a, 4b, 4′b), and
a formation of a plurality of charge detectors capacitively coupled to the quantum dots of the plurality of quantum dots, said formation being configured such that each charge detector comprises a portion located between the gates of the first set of gates.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A, 2A, 3A, 4A, 5A, 6A, 7A, 8A, 9A, 10A and 11A schematically illustrate, as a cross-section, steps of manufacturing a quantum device, according to an embodiment of the present invention.

FIGS. 1A, 2B, 3B, 4B, 5B, 6B, 7B, 8B, 9B. 10B and 11B schematically illustrated, as a top view, the manufacturing steps illustrated in corresponding FIGS. 1A, 2A, 3A, 4A, 5A, 6A, 7A, 8A, 9A, 10A and 11A according to an embodiment of the present invention.

FIG. 10C illustrates, as a perspective, the step of manufacturing the quantum device illustrated in FIGS. 10A and 10B, according to an embodiment of the present invention.

FIG. 12 schematically illustrates, as a cross-section, a quantum device, according to a first embodiment of the present invention.

FIG. 13 schematically illustrates, as a cross-section, a quantum device, according to a second embodiment of the present invention.

FIG. 14 schematically illustrates, as a top view, a quantum device, according to a first embodiment of the present invention.

FIG. 15 schematically illustrates, as a top view, a quantum device, according to a second embodiment of the present invention.

FIG. 16 schematically illustrates, as a top view, a quantum device, according to a third embodiment of the present invention.

FIG. 17 schematically illustrates, as a top view, a quantum device, according to a fourth embodiment of the present invention.

FIG. 18 schematically illustrates, as a cross-section, a quantum device, according to a third embodiment of the present invention.

FIG. 19 schematically illustrates, as a cross-section, a quantum device, according to a fourth embodiment of the present invention.

The drawings are given as examples, and are not limiting of the invention. They constitute principle schematic representations, intended to facilitate the understanding of the invention, and are not necessarily to the scale of practical applications. In particular, on the principle diagrams, the thicknesses and/or the dimensions of the different layers, patterns and raised elements are not representative of reality. For reasons of clarity, all of the alphanumerical references are not systematically repeated from one figure to another. It is understood that the elements already described and referenced, when they are reproduced on another figure, typically have the same alphanumerical references, even if these are not explicitly mentioned. A person skilled in the art will identify, without difficulties, one same element reproduced on different figures.

### DETAILED DESCRIPTION

Before starting a detailed review of embodiments of the invention, optional features are stated below, which can optionally be used in association or alternatively:

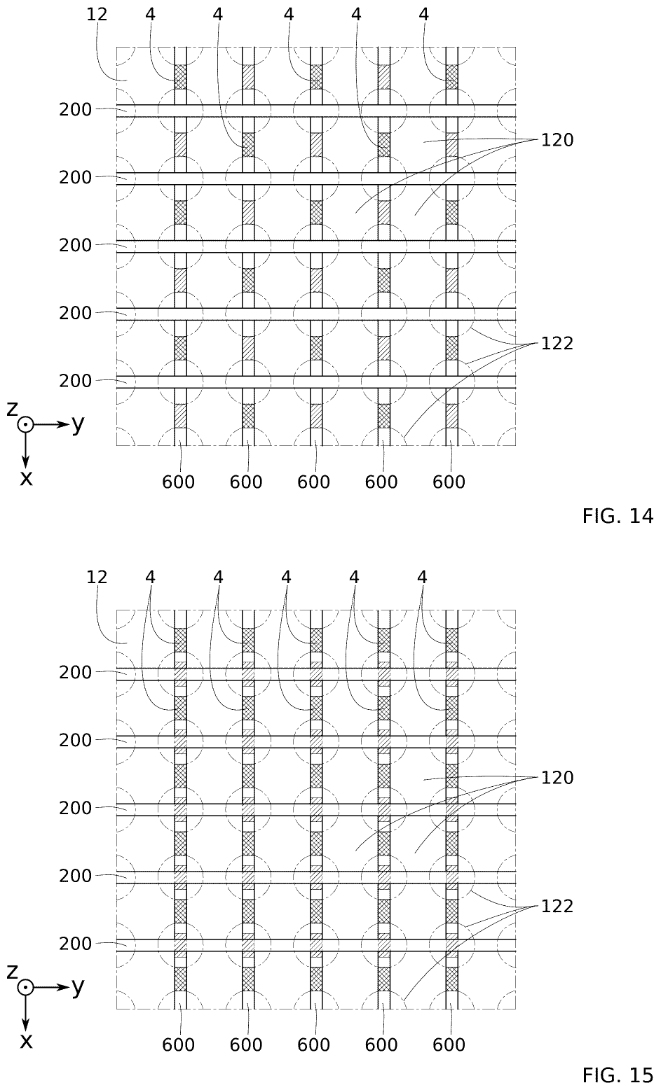

According to an example, each charge detector is located under the gates of the second set of gates. Typically, the gates of the second set of gates are arranged in lines which are parallel to one another, and the charge detectors are located within these lines. A gate of the second set, in the form of a line, thus typically surmounts several charge detectors. The charge detectors are not located under the gates of the first set of gates. Typically, the gates of the first set of gates are arranged in lines which are parallel to one another, and the charge detectors are located between these lines. The gates of the first set of gates and the gates of the second set of gates are typically perpendicular to one another. The position of the charge detectors is, for example, illustrated in FIGS. 14 to 17, according to different embodiments.

According to an example, the device comprises a dielectric layer on the semiconductive layer, and the portion of each charge detector located between the gates of the first set of gates is directly in contact with said dielectric layer. The detectors are thus closest to the quantum dots.

According to an example, the at least one charge reservoir is one single charge reservoir common to each charge detector, for a given gate of the second set of gates. Typically, when the second gates are arranged in lines which are parallel to one another, the charge reservoir is common to each charge detector for a given line of second gates. When there are several lines of second gates, said lines being independent from one another, there are typically as many charge reservoirs as independent lines.

According to an example, each charge detector comprises a conductive island and at least one charge reservoir separated from one another by a dielectric barrier. Thus, each detector can be of the single electron transistor (SET) type, or of the single-load quantum dot (SLQD) type.

According to an example, the portion of each charge detector located between the gates of the first set is a conductive island. The conductive island is sensitive to the electrostatic environment. It is thus advantageously located in the proximity of the quantum dots located under the control gate level considered. The sensitivity of detecting charges in the quantum dots is thus improved.

According to an example, each charge detector comprises one single charge reservoir. According to this example, the charge detectors are preferably of the single-load quantum dot (SLQD) type. The reservoir is typically presented in the form of a gate or of a gate line surmounting all the detectors of this same line.

According to an alternative example, each charge detector comprises two separate charge reservoirs, of the source and drain type. According to this example, the charge detectors are preferably of the single electron transistor (SET) type.

According to an example, the portion of each charge detector is located between the control gates of the first set of control gates. The proximity of the charge detector with the quantum dots is optimised. The detection sensitivity is optimised.

According to an example, each control gate of the first set comprises a first stage and a second stage, separated by a dielectric barrier, the device being configured such that all the second stages can be biased, independently from one another, so as to control a chemical potential of the portion of each charge detector. The portion of each charge detector located between the control gates of the first set can thus be biased according to an extended bias range. A scanning over the biases of this bias range can advantageously be performed, in order to determine a number of charges present in the quantum dot(s) located under said first set.

According to an example, the first stages of the control gates of the first set are configured to control the quantum dots.

According to an example, the control gates of the first set and the gates of the second set form a grid pattern, projecting along a first direction z, and the quantum dots are located in vertical alignment with the empty spaces of the grid pattern.

According to an example, the charge detectors are located in vertical alignment with tunnel barriers separating the quantum dots from one another.

According to an example, the two-dimensional quantum dot matrix is organised along a first array having a first pitch and the charge detectors are organised along a second array having a second pitch, equal to twice the first pitch.

According to an example, the plurality of quantum dots comprises more than sixteen quantum dots arranged in a two-dimensional matrix, preferably more than thirty-two quantum dots arranged in a two-dimensional matrix, preferably more than one hundred and twenty-eight quantum dots arranged in a two-dimensional matrix.

According to an example, the plurality of quantum dots comprises N quantum dots and the plurality of charge detectors comprises N/2 charge detectors, such that each charge detector is associated with two quantum dots of the two-dimensional matrix. In a known manner, in particular by the prior measuring of stability diagrams, the signals detected by the detectors can be connected to one another of the quantum dots. This enables the distinction between the different quantum dots associated with a detector. The association of two quantum dots with a detector has, for example, an advantageous application in the scope of the implementation of a quantum error corrective code, for example, of the “surface code” type. In this case, it is necessary to read only the information stored on half of the quantum dots corresponding to “measuring” qubits, read periodically to detect errors, the other half of the quantum dots corresponding to “data” qubits not measured during a calculation to not impact the quantum information that they encode.

According to an example, for four adjacent control gates of the first set called successively first, second, third and fourth control gates, the device comprises a first conductive island of a first charge detector between the first and second control gates, said first conductive island being surmounted by a first dielectric barrier portion connecting the first and second control gates, and a second conductive island of a second charge detector between the third and fourth control gates, said second conductive island being surmounted by a second dielectric barrier portion connecting the third and fourth control gates.

According to an example, the two-dimensional quantum dot matrix and the charge detectors are respectively organised along arrays having one same pitch.

According to an example, the plurality of quantum dots comprises N quantum dots and the plurality of charge detectors comprises N charge detectors, such that each charge detector is associated with a quantum dot of the two-dimensional matrix. Each detector is thus typically associated with one single quantum dot. This makes it possible to essentially increase the charge detection signal over the entire array. The detection is thus less noisy and more precise.

According to an example, the first and second sets of gates are configured to locally confine a particle or a charge. According to an example, the device comprises a third set of gates configured to control a chemical potential of the quantum dots. This makes it possible to fill or empty the quantum dots. This makes it possible to handle the quantum information.

According to an example, the plurality of charge detectors is integrated in one from among the first, second and third sets of gates. For example, the integration of charge detectors in the third set of gates and directly in vertical alignment with a quantum dot enables a better measuring sensitivity regarding the latter.

According to an example, the gates of the second set are configured to control the charge detectors by reflectometry, preferably by common potential, by being connected to a series induction and capacity. The charge detectors are thus fully integrated within the sets of gates, in particular, between the control gates of the quantum dots.

According to an example, the formation of the plurality of charge detectors comprises the formation of conductive islands between the control gates of the first set of gates, and the formation of a dielectric barrier on said conductive islands, before the formation of the second set of gates. The dielectric barrier typically separates the conductive islands from a charge reservoir.

According to an example, the control gates of the first set are oriented along a second direction x and the gates of the second set are oriented along a third direction y perpendicular to the second direction x.

According to an example, the formation of the dielectric barrier comprises a structuration configured to form dielectric barrier portions in the form of bands oriented diagonally opposite the second and third directions x, y, such that there are fewer charge detectors formed than quantum dots formed, typically twice fewer. The intersections, projecting along the first direction z, between the bands and the control gates of the first level defining the charge detectors. According to the width and the orientation of the bands, it is thus possible to form a detector subarray from among the two-dimensional quantum dot array.

According to an example, the method comprises a connection of the gates of the second set to a series induction and capacity, and a controlling of the charge detectors by reflectometry.

Unless incompatible, it is understood that all of the optional features above can be combined, so as to form an embodiment which is not necessarily illustrated or described. Such an embodiment is clearly not excluded from the invention. The features and the advantages of an aspect of the invention, for example, the device or the method, can be adapted mutatis mutandis to the other aspect of the invention.

It is specified that, in the scope of the present invention, the terms “on”, “surmounts”, “covers”, “underlying”, “opposite” and their equivalents do not necessarily mean “in contact with”. Thus, for example, the deposition, the assembly or the application of a first layer on a second layer, does not compulsorily mean that the two layers are directly in contact with one another, but means that the first layer covers, at least partially, the second layer by being either directly in contact with it, or by being separated from it by at least one other layer, or at least one other element.

By a substrate, a film, a layer “with the basis” of a material A, this means a substrate, a film, a layer comprising this material A only or this material A and optionally other materials, for example, doping elements or alloy elements.

Below, the first, second and/or third sets of gates are also respectively called first, second and/or third gate levels. A gate “level”, like an interconnecting or metallisation level, corresponds typically to a layer or a set of structured layers of a microelectronic circuit, along the direction usually given in the field of microelectronics.

In operation, the device comprises quantum dots regularly distributed in the semiconductive layer, in the form of a two-dimensional matrix. These quantum dots are not necessarily physically defined when the device does not operate. The quantum dots can correspond to confinement zones created in the semiconductive layer, when one or more voltages are applied to the different gates of the device. The semiconductive layer is therefore adapted to the formation of quantum dots.

The gates disposed above the quantum dots, typically the first gates, control the coupling between the quantum dots. The gates disposed between quantum dots, typically the second gates, control the barriers between these quantum dots.

The quantum dots can be laterally confined in the semiconductive layer by structural elements, typically holes formed in the semiconductive layer. The lateral confinement of the quantum dots can also be achieved electrically, using two first gates and two second gates.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequence of phases of the method.

By “selective etching with respect to” or “etching having a selectivity with respect to” means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A preferably orthonormal system, comprising the axes x, y, z is represented in the accompanying figures. When one single system is represented on one same set of figures, this system is applied to all the figures of this set.

In the present patent application, thickness will preferably be referred to, for a layer or a film, and height will preferably be referred to, for a device or a structure. The thickness is taken along a direction normal to the main extension plane of the layer or of the film. Thus, a superficial silicon layer typically has a thickness along z. A gate pattern formed on such a superficial layer has a height along z. The relative terms “on”, “surmounts”, “under”, “underlying” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another element means that these two elements are both located on one same line perpendicular to a plane in which a lower or upper face of a substrate mainly extends, i.e. on one same line oriented vertically in the figures, as a cross-section.

The terms “substantially”, “around”, “about” mean plus or minus 10%, and preferably, plus or minus 5%. Moreover, the terms “between . . . and . . . ” and equivalents mean that the limits are inclusive, unless mentioned otherwise.

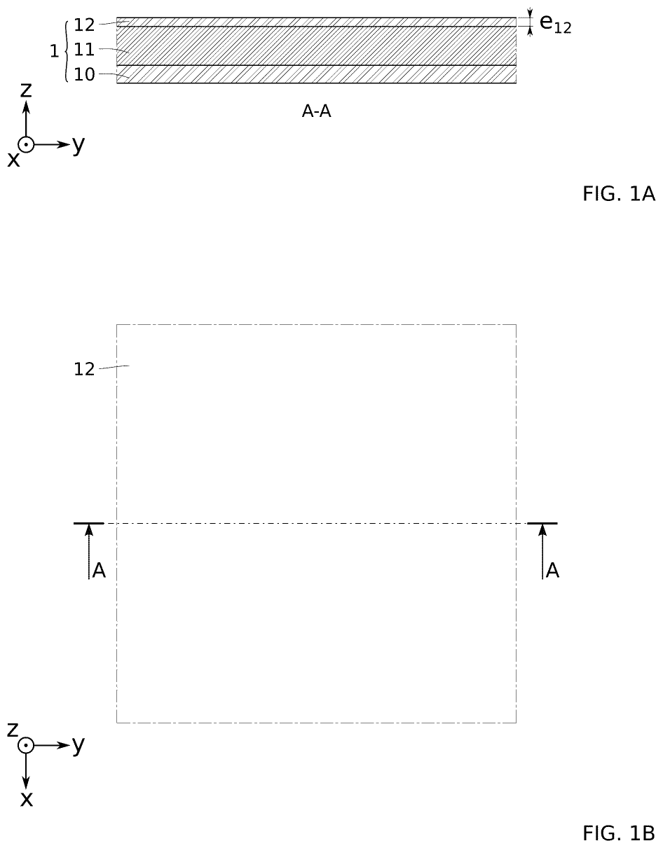

FIGS. 1A-11A schematically illustrate, as a cross-section, steps for manufacturing a quantum device comprising charge detectors, according to a first embodiment. FIGS. 1B-11B schematically illustrate, as a perspective, the manufacturing steps illustrated in corresponding FIGS. 1A-11A.

As illustrated in FIGS. 1A, 1B, the first steps consist of providing a silicon-on-insulator (SOI)-type substrate 1, comprising a support layer 10, typically a so-called “bulk” silicon substrate, a so-called “BOX” buried oxide layer 11, a so-called “topSi” superficial silicon layer 12. The topSi layer 12 typically has a thickness e₁₂ of around 5 nm to 20 nm. This topSi layer 12 is intended to contain the quantum dots. These quantum dots can subsequently be formed, by simple electrostatic confinement within the topSi layer 12. Alternatively, they can be created physically, for example, by forming holes regularly distributed in the topSi 12 (not illustrated).

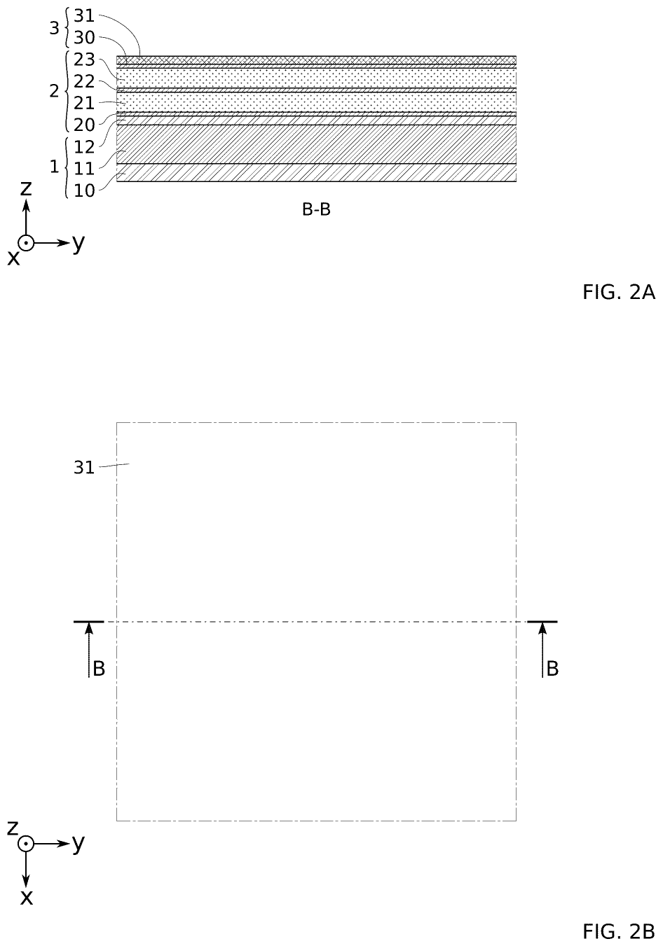

As illustrated in FIGS. 2A, 2B, a gate stack 2 is formed on the substrate 1. This stack 2 is intended to form, after structuration, the first gate level of the device. This stack 2 typically comprises, along z starting with the substrate 1, a dielectric layer 20, a first conductive layer 21, for example, metal- or doped polycrystalline silicon-based, a dielectric layer 22, a second conductive layer 23, for example, metal- or doped polycrystalline silicon-based. The stack 2 is surmounted by a masking layer 3 typically comprising a silicon oxide layer 30 and/or a silicon nitride layer 31. This masking layer 3 is intended to form, after structuration, a hard mask for the etching of the stack 2.

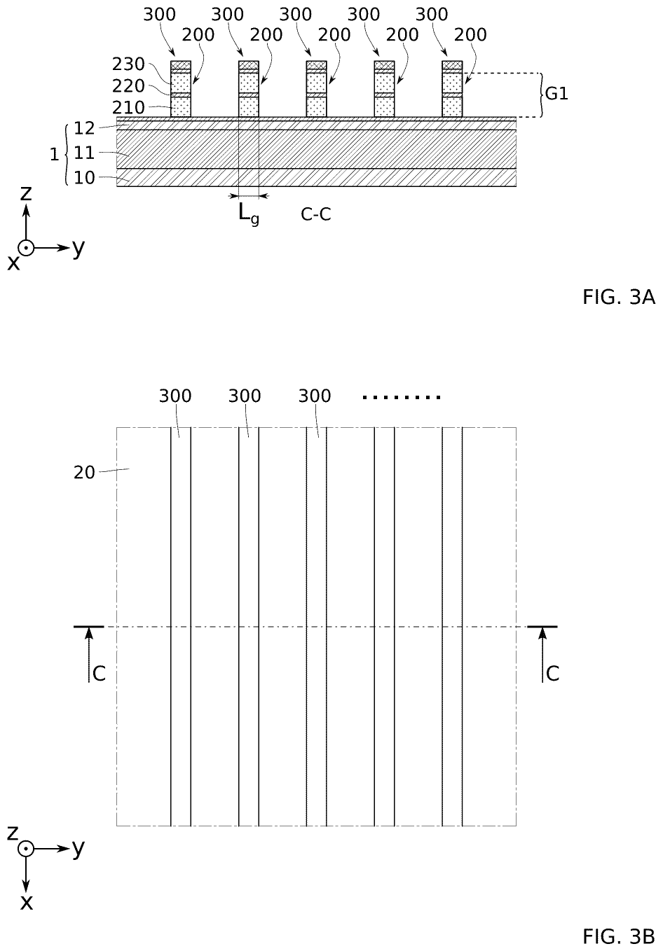

As illustrated in FIGS. 3A, 3B, the masking layer 3 is first structured by lithography and etching to form a hard mask 300 defining first gate patterns on the stack 2, aligned along x in this example. The stack 2 is then etched, typically by an anisotropic dry etching along z, to form gates 200. A reactive ion etching (RIE) or a fluorocarbon species-based plasma etching can be used to successively etch the layers 23, 22 and 21 of the stack 2. The etching of the stack 2 is configured to stop on the dielectric layer 20. Each gate 200 thus comprises a first stage 210, a dielectric barrier 220, a second stage 230. The gates 200 form the first gate level G1 of the device. The gates 200 are surmounted at this stage by the hard mask 300. The gates 200 have a dimension by width along y L_{g}. The first stage 210 of the gates 200 is typically configured to control qubits in the quantum dots. The second stage 230 of the gates 200 is typically configured to control the charge detectors associated with the quantum dots.

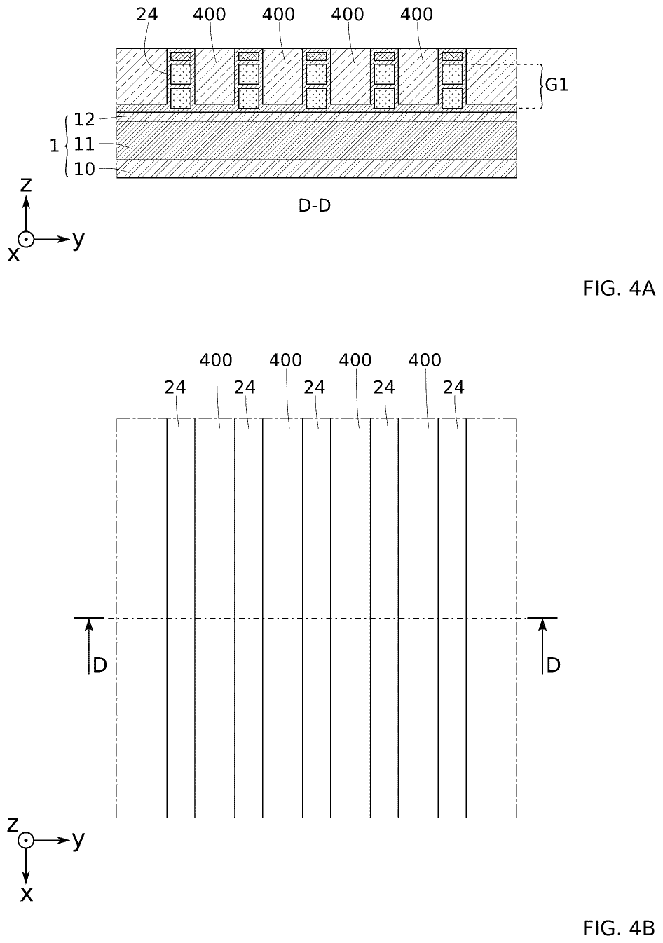

As illustrated in FIGS. 4A, 4B, a dielectric layer 24, also called liner, is deposited consistently over the exposed parts of the dielectric layer 20, on the flanks of the gates 200 and on the hard mask 300. The spaces located between the gates 200 are then filled by deposition of a conductive layer, for example, so-called polySi polycrystalline silicon-based. A planarisation, typically by chemical-mechanical polishing (CMP), is then performed, stopping on the dielectric layer 24 at the top of the gates surmounted by the hard mask. Conductive islands 400 are thus formed between the gates of the first gate level of the device. These conductive islands 400 are typically “self-aligned”. They are directly formed between the gates of the first level, and therefore aligned opposite said gates, without this requiring any lithography step.

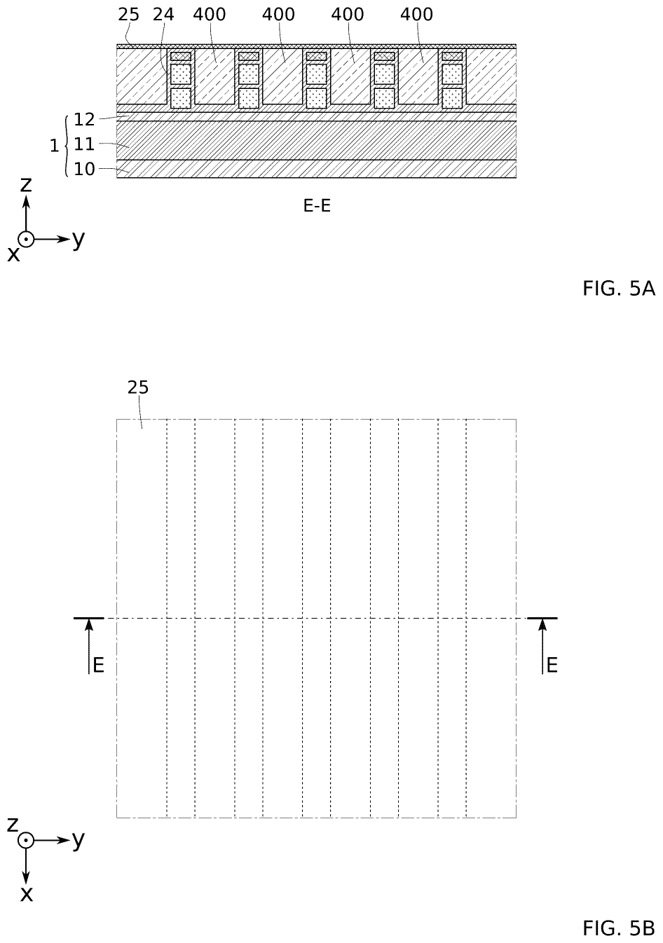

As illustrated in FIGS. 5A, 5B, a dielectric layer 25 is deposited continuously over all of the conductive islands 400 and over the exposed parts of the dielectric layer 24. The dielectric layer 25 is intended to separate an electric charge reservoir, typically located above this layer 25, from the conductive islands 400 located under this layer 25. The dielectric layer 25 is configured to remain permeable to the passage of electric charges between the charge reservoir and the conductive islands 400.

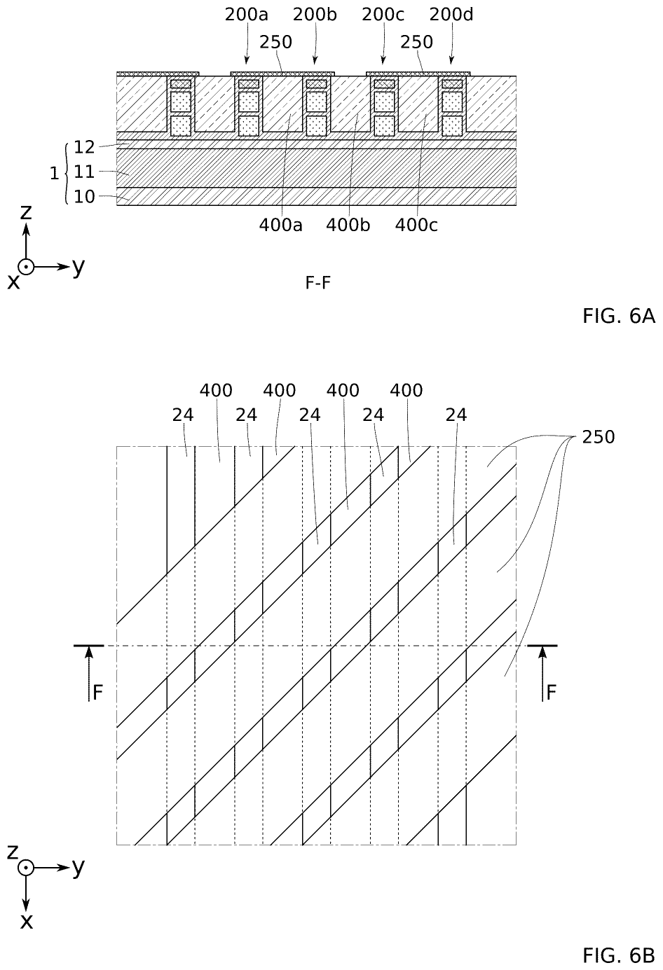

As illustrated in FIGS. 6A, 6B, this dielectric layer 25 is then structured by etching, typically in the form of bands oriented diagonally opposite the underlying gates, for example, at 45° opposite the axes, x, y (FIG. 6B). This makes it possible to periodically cover one conductive island 400 out of two along the directions x and y. Thus, as illustrated in FIG. 6A, as a cross-section, along the cutting line A-A represented in FIG. 6B, for four successive gates 200a, 200b, 200c, 200d, only the conductive islands 400a and 400c respectively located between the gates 200a, 200b and 200c, 200d, are covered by a dielectric barrier portion 250. The conductive island 400b located between the gates 200b, 200c is not covered along the cutting line A-A.

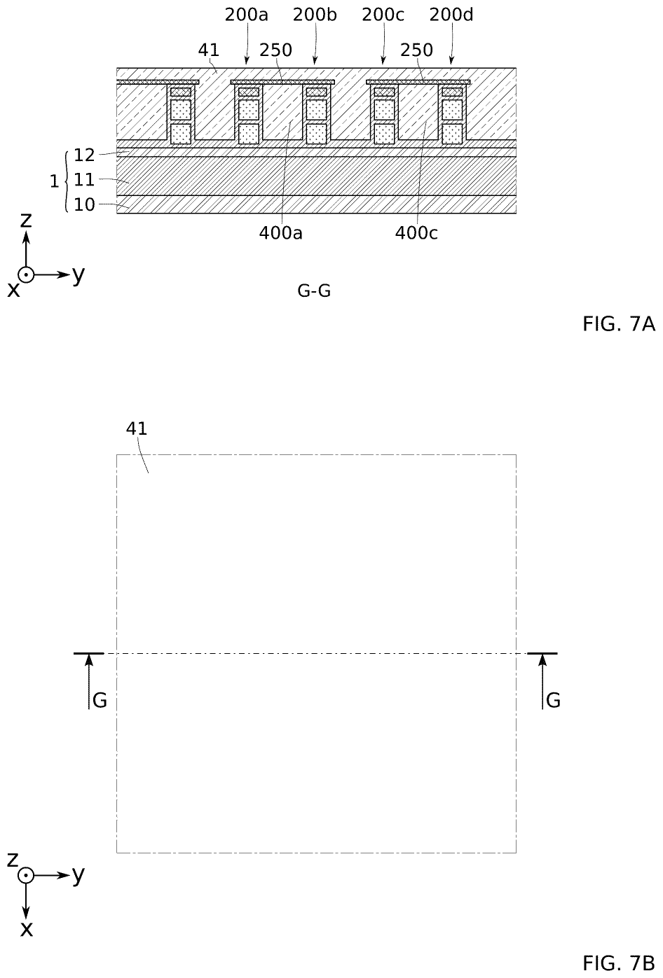

As illustrated in FIGS. 7A, 7B, a conductive layer 41, typically polySi-based, is then deposited, then planarised by CMP. This conductive layer 41 is intended to form a charge reservoir for the conductive islands 400a, 400c of the charge detectors. The conductive layer 41 is separated from the conductive islands 400a, 400c by the dielectric barrier portions 250.

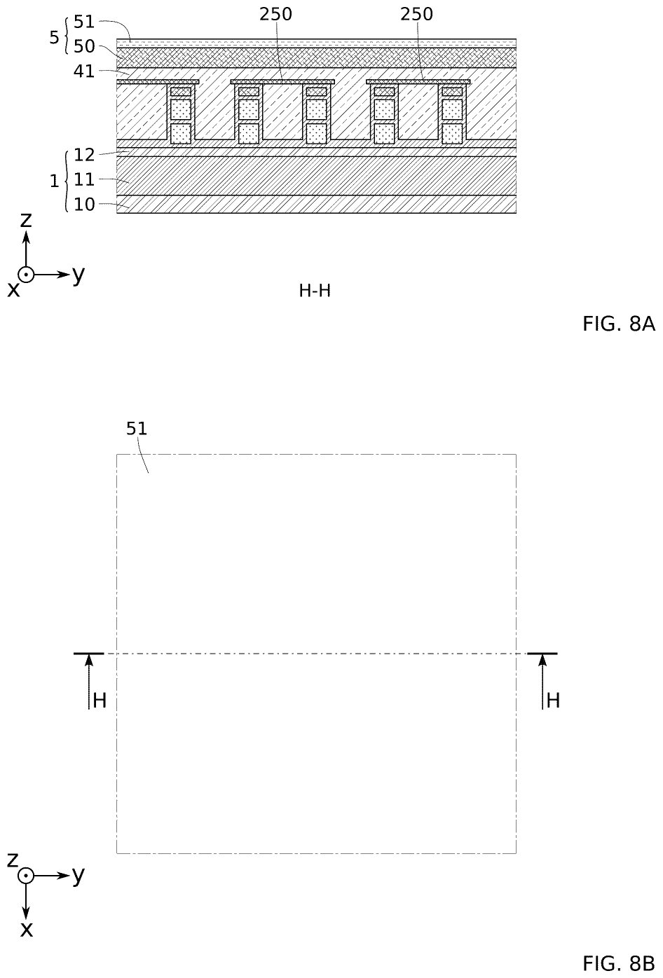

As illustrated in FIGS. 8A, 8B, a masking layer 5 typically comprising a silicon nitride layer 50 and/or a silicon oxide layer 51 is deposited on the conductive layer 41.

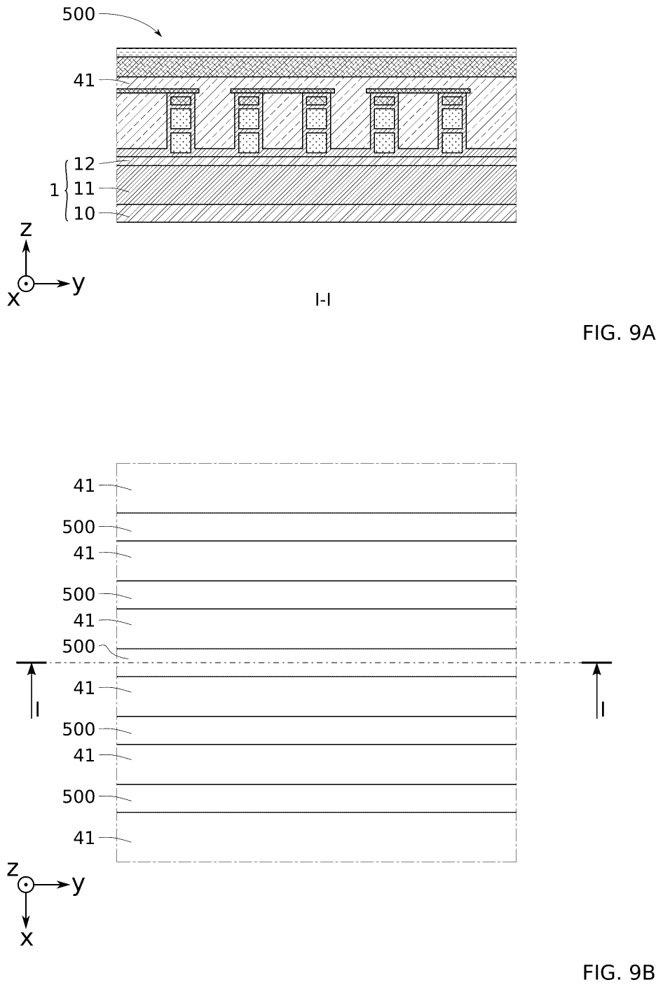

As illustrated in FIGS. 9A, 9B, the masking layer 5 is then structured by lithography and etching to form a hard mask 500 defining second gate patterns, aligned along y, in this example.

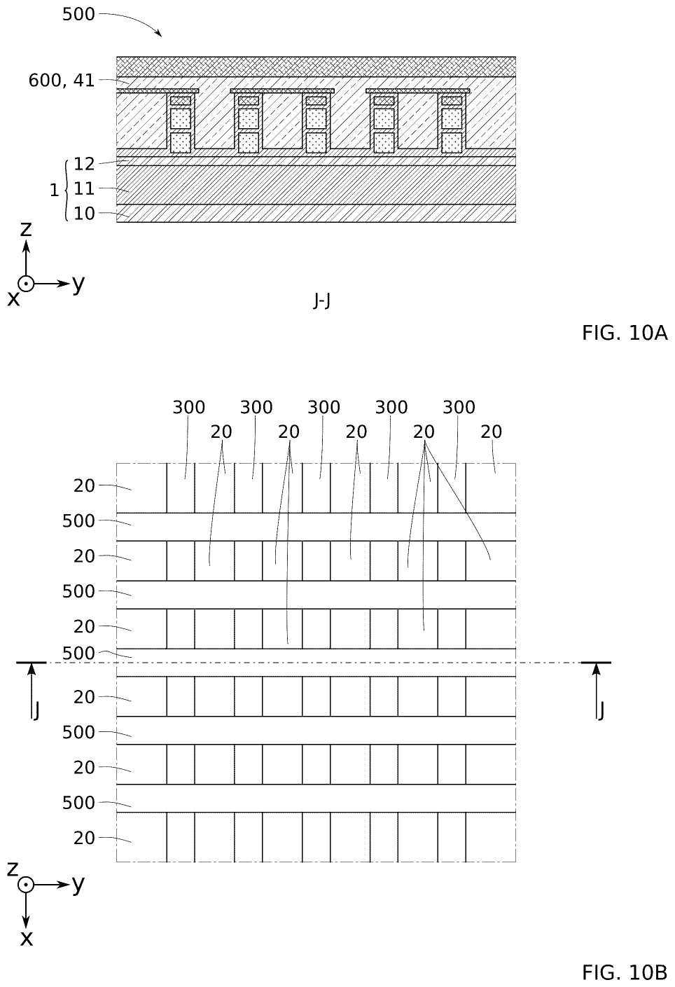

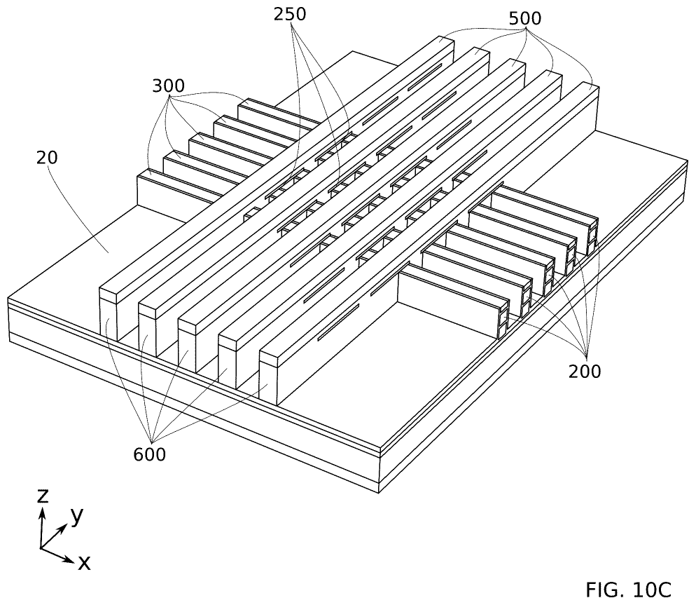

As illustrated in FIGS. 10A, 10B, 10C, an anisotropic dry etching along z is then performed, to form gates 600. This etching typically makes it possible to remove the parts of the layer 41 and of the conductive islands 400 not covered by a hard mask. The etching is typically configured to stop in the hard mask 300, at the SiN layer of the hard mask 300, in the hard mask 500, at the SiN layer of the hard mask 500, and on the dielectric layer 20 between the hard masks 300, 500.

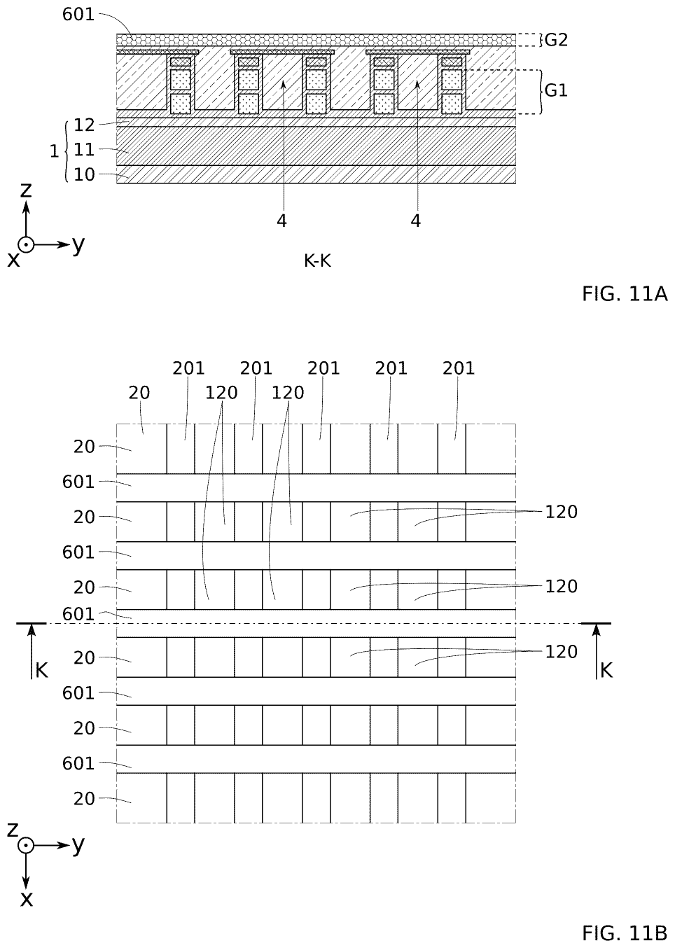

As illustrated in FIGS. 11A, 11B, the exposed parts of the hard masks 300, 500, mainly SiN-based, are removed selectively at the dielectric layer 20 at the bottom of the trenches and cavities bordering the gates 200, 600. The top of the polySi-based gates 200, 600 is thus exposed. A silicidation of the gates 200, 600 is then performed, conventionally, to obtain top parts 201, 601 of silicided gates. Seen from above (FIG. 11B), the mesh of the gates 200, 600 makes it possible to define a two-dimensional quantum dot matrix. The quantum dots 120 are located in the inter-gate spaces, between the gates 200, 600, projecting along z (FIG. 11B). The quantum dots 120 are confined in the topSi. The charge detectors 4 are integrated in the gate levels G1, G2 of the device.

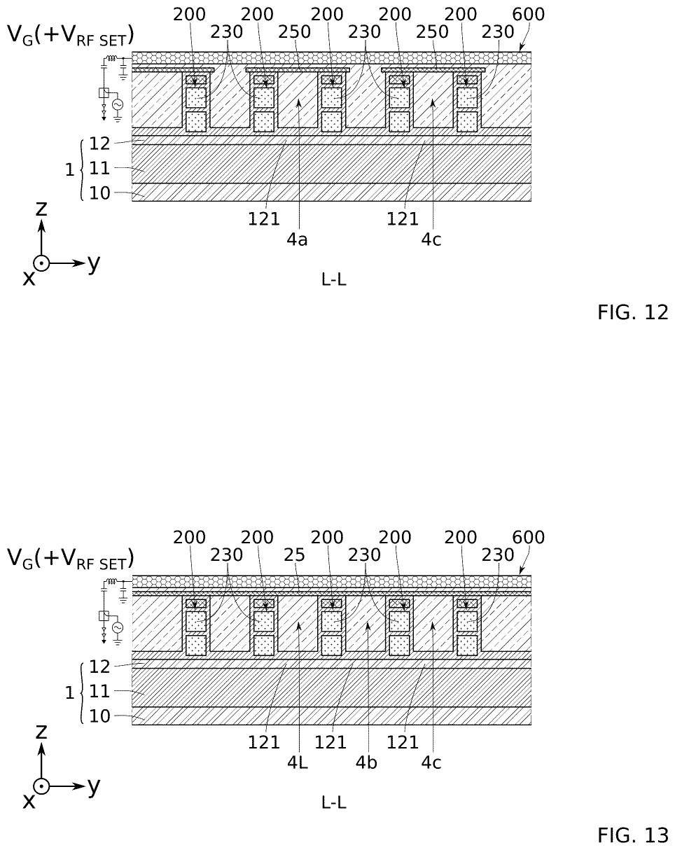

The device illustrated in FIG. 12 is thus obtained. This device comprises quantum dots 120 in the topSi layer 12, located between the different gate 200, 600 intersections. The device further comprises SLQD-type charge detectors 4a, 4c partially formed between the gates 200 under the dielectric barrier portions 250. The charge detectors are located above the tunnel barriers 121 connecting two quantum dots to one another. In this example, the device comprises twice fewer charge detectors than quantum dots 120. An operation of the charge detectors 4a, 4c by reflectometry can advantageously be considered, by connecting the gates 600 to a reflectometry system comprising a series capacity and induction. This configuration corresponds to a detection by reflectometry by common potential, insofar as all the detectors 4a, 4c are probed by one same gate 600.

A biasing of the charge detectors 4a, 4c through second stages 230 of gates 200 can advantageously be performed, to probe the presence of charges in the quantum dots 120. The charge detector 4a and the charge detector 4c can be biased independently from one another.

Other embodiments of the device can be considered.

FIG. 13 illustrates an embodiment of the device in which a charge detector 4a, 4b, 4c is provided for each quantum dot 120. In this embodiment, the dielectric layer 25 forms a continuous barrier above the conductive islands of the charge detectors 4a, 4b, 4c. It is sufficient to not structure this dielectric layer 25, such as illustrated in FIGS. 5A, 5B, to obtain the device illustrated in FIG. 13. The detectors can operate by reflectometry by common potential, as above. A biasing of the charge detectors 4a, 4b, 4c through second stages 230 of gates 200 can advantageously be performed, to probe the presence of charges in the quantum dots 120. The charge detectors 4a, 4b, 4c can be biased independently.

FIG. 14 illustrates, as a top view, a 2D array arrangement of quantum dots 120 located between the intersections of the gates 200 and 600, associated with a subarray of detectors 4 twice fewer than the quantum dots 120, similarly to the architecture presented in FIG. 12. In this example, holes 122 are formed in the topSi layer 12 to add a structural confinement assisting with the definition of the quantum dots 120. The quantum dots 120 are located between the holes 122. The detectors 4 are located in vertical alignment with certain tunnel barriers separating the quantum dots 120.

FIG. 15 illustrates, as a top view, a 2D array arrangement of quantum dots 120 located between the intersections of the gates 200 and 600, associated with a subarray of detectors 4, as many as the quantum dots 120, similarly to the architecture presented in FIG. 13. In this example, holes 122 are formed in the topSi layer 12 to add a structural confinement assisting with the definition of the quantum dots 120. The quantum dots 120 are located between the holes 122. The detectors 4 are located in vertical alignment with tunnel barriers separating the quantum dots 120.

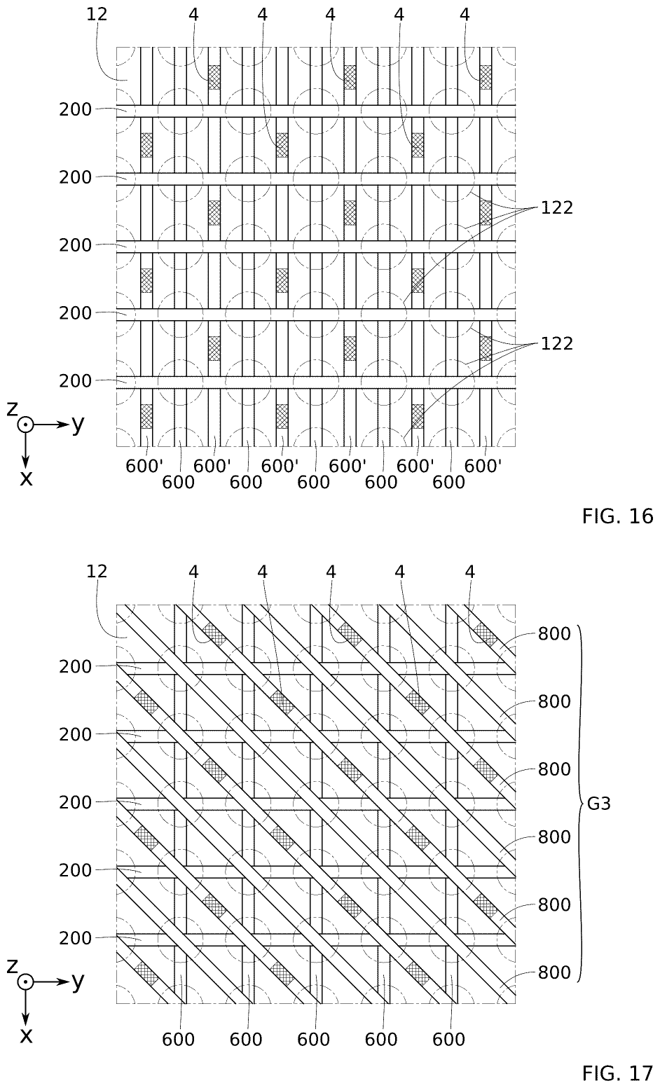

FIG. 16 illustrates, as a top view, a 2D array arrangement of quantum dots 120 located between the intersections of the gates 200 and 600. In this example, the gates 600, 600′ of the second level have been doubled—the pitch of the array along y has been divided by two—so as to obtain both a control of the tunnel barriers by the gates 600 and a control of the chemical potentials of the quantum dots by the gates 600′. In this example, the subarray of detectors 4 comprises twice fewer detectors than the quantum dots 120. The quantum dots 120 are located between the holes 122. The detectors 4 are located in vertical alignment with certain quantum dots 120. The gates 600, 600′ of the second level can be achieved simultaneously. Alternatively, the gates 600′ can be formed after the gates 600, for example, on a third gate level of the device. A person skilled in the art will know how to adapt the formation of the different gate levels as needed.

FIG. 17 illustrates, as a top view, a 2D array arrangement of quantum dots 120 located between the intersections of the gates 200 and 600. In this example, a third gate 800 level G3 has been added above the first and second gate 200, 600 levels to control the chemical potentials of the quantum dots 120. The charge detectors 4 can be integrated under the gates 800 of this third level. According to an option not illustrated, the charge detectors 4 can be integrated between the gates 800 of this third level, for example, in vertical alignment with certain tunnel barriers.

The device architecture of the present invention thus makes it possible to consider a multitude of configurations for the placement of detectors 4 between the gates of at least one gate level. Such an architecture is advantageously compact and versatile.

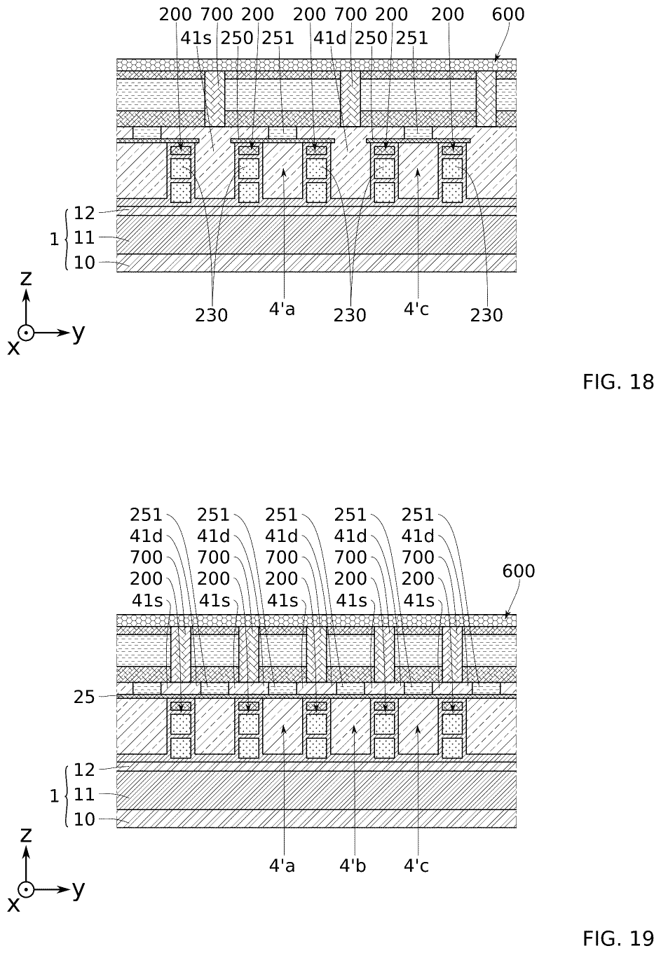

FIGS. 18 and 19 illustrate two other embodiments of the device in which the charge detectors are of the SET type, with two “source and drain” charge reservoirs 41s, 41d associated with a conductive island via the dielectric barrier 250, 25. The two charge reservoirs 41s, 41d are typically separated by a dielectric block 251 surmounting the dielectric barrier 250, 25, around equal distance from the gates 200.

FIG. 18 illustrates a first embodiment in which the device comprises twice fewer SET-type charge detectors 4′a, 4′c than quantum dots 120. The two charge reservoirs 41s, 41d are typically connected to the gate 600 by vias 700. As above, an operation of the charge detectors 4′a, 4′c by reflectometry can advantageously be considered, by connecting the gates 600 to a reflectometry system.

FIG. 19 illustrates a second embodiment in which the device comprises as many SET-type charge detectors 4′a, 4′b, 4′c than quantum dots 120. The two charge reservoirs 41s, 41d are typically connected to the gate 600 by vias 700. As above, an operation of the charge detectors 4′a, 4′b, 4′c by reflectometry can advantageously be considered, by connecting the gates 600 to a reflectometry system.

Given the description above, it clearly appears that the device proposed offers a particularly effective and versatile solution to integrate charge detectors in the gate levels associated with a 2D quantum dot matrix, by improving the compactness and the sensitivity of this quantum device.

The invention is not limited to the embodiments described above.

1. A quantum device comprising:
a semiconductive layer configured to form a plurality of quantum dots arranged in a two-dimensional quantum dot matrix;
a plurality of charge detectors capacitively coupled to the plurality of quantum dots,
a first set of gates comprising control gates of the plurality of quantum dots surmounting the semiconductive layer, and
a second set of gates comprising gates configured to form at least one charge reservoir for the charge detectors,
wherein each charge detector comprises a portion located between the gates of the first set of gates, and each control gate of the first set of gates comprises a first stage and a second stage separated by a dielectric barrier, the device being configured such that all the second stages can be biased independently from one another, so as to control a chemical potential of the portion of each charge detector.

2. The device according to claim 1, wherein the first stages of the control gates of the first set of gates are configured to control the plurality of quantum dots.

3. The device according to claim 1, wherein the at least one charge reservoir is one single charge reservoir common to each charge detector for a given gate of the second set of gates, the charge detectors being of the single-lead quantum dot type.

4. The device according to claim 1 comprising a dielectric layer on the semiconductive layer, wherein the portion of each charge detector located between the gates of the first set of gates is directly in contact with the dielectric layer.

5. The device according to claim 1, wherein the portion of each charge detector located between the gates of the first set of gates is a conductive island.

6. The device according to claim 1, wherein the charge detectors are located in vertical alignment with the quantum dots, along a first direction.

7. The device according to claim 1, wherein the two-dimensional quantum dot matrix is organised along a first array having a first pitch and the charge detectors are organised along a second array having a second pitch, equal to twice the first pitch, and wherein the plurality of quantum dots comprises N quantum dots and the plurality of charge detectors comprises N/2 charge detectors, such that each charge detector is associated with two quantum dots of the two-dimensional matrix.

8. The device according to claim 7 for four adjacent control gates of the first set of gates, called successively first, second, third and fourth control gates, the device comprises a first conductive island of a first charge detector between the first and second control gates, the first conductive island being surmounted by a first dielectric barrier portion connecting the first and second control gates, and a second conductive island of a second charge detector between the third and fourth control gates, the second conductive island being surmounted by a second dielectric barrier portion connecting the third and fourth control gates.

9. The device according to claim 1, wherein the two-dimensional quantum dot matrix and the charge detectors are respectively organised along arrays having one same pitch, and wherein the plurality of quantum dots comprises N quantum dots and the plurality of charge detectors comprises N charge detectors, such that each charge detector is associated with a quantum dot of the two-dimensional matrix.

10. The device according to claim 1, wherein the gates of the second set of gates are configured to control the charge detectors by reflectometry by being connected to a series induction and capacity.

11. A method for producing the quantum device according to claim 1, comprising:
forming the semiconductive layer configured to comprise the plurality of quantum dots arranged in the two-dimensional matrix,
forming the first set of gates comprising the control gates of the quantum dots, surmounting the semiconductive layer,
forming the second set of gates comprising the gates configured to form the at least one charge reservoir for the charge detectors, and
forming the plurality of charge detectors capacitively coupled to the quantum dots of the plurality of quantum dots, the plurality of charge detectors being configured such that each charge detector comprises the portion located between the gates of the first set of gates.

12. The method according to claim 11, wherein forming the plurality of charge detectors comprises forming conductive islands between the control gates of the first set of gates, and forming a dielectric barrier on the conductive islands before forming the second set of gates.

13. The method according to claim 12, wherein the control gates of the first set are oriented along a second direction and the gates of the second set are oriented along a third direction perpendicular to the second direction, and wherein forming the dielectric barrier comprises a structuration configured to form dielectric barrier portions in a form of bands oriented diagonally opposite the second and third directions such that the charge detectors formed are fewer than the quantum dots formed.

14. The method according to claim 11 comprising connecting the gates of the second set to a series induction and capacity, and controlling the charge detectors by reflectometry.

15. The method according to claim 13 wherein the charge detectors formed are twice fewer than the quantum dots formed.
